(19) United States
(12) Patent Application Publication
(10) Pub. No.: US 2006/0144332 A1
(43) Pub. Date: Jul. 6, 2006

(54) Controlled flow of source material via droplet evaporation

(76) Inventors: Joseph D. Sweeney, New Milford, CT (US); Jose Arno, Brookfield, CT (US)

Correspondence Address: ATMI, INC., 7 COMMERCE DRIVE, DANBURY, CT, 06810, US

(21) Appl. No.: 11/028,743

(22) Filed: Jan. 4, 2005

(51) Int. Cl. C23C 16/00

(52) U.S. Cl. 118/715; 118/726

(57) ABSTRACT

A system for delivering a controlled and stable flow of vaporizable source material for use in semiconductor manufacturing applications. The system includes a droplet generator, which includes a plurality of nozzles and a pressure producing means. When sufficient pressure is applied to a liquefied or liquefiable source material, droplets of the source material are generated and ejected from the nozzles into a downstream processing tool or source/vaporization chamber. The pressure is applied either through the use of a heating element or an electromechanical transducer.

### BACKGROUND OF INVENTION

1. Field of the Invention

The present invention relates to a delivery system, and more particularly, to a system for delivering a controlled and reproducible flow of vaporizable source material for use in chemical vapor deposition (CVD), ion implantation and other semiconductor manufacturing process systems.

2. Description of Related Art

Chemical vapor deposition has been extensively used for preparation of films and coatings in semiconductor wafer processing. CVD is a favored deposition process in many respects, for example, because of its ability to provide highly conformal and high quality films, at relatively fast processing times. Further, CVD is beneficial in coating substrates of irregular shapes including the provision of highly conformal films even with respect to deep contacts and other openings.

In general, CVD techniques involve the delivery of gaseous reactants to the surface of a substrate where chemical reactions take place under temperature and pressure conditions that are favorable to the thermodynamics of the desired reaction. The type and composition of the layers that can be formed using CVD is limited by the ability to deliver the reactants or reactant precursors to the surface of the substrate. Various liquid reactants and precursors are successfully used in CVD applications by delivering the liquid reactants in a carrier gas. For example, in liquid reactant CVD systems, the delivery of a precursor is carried out using the sublimator/bubbler method in which the precursor is usually placed in a sublimator/bubbler reservoir which is then heated to the sublimation temperature of the precursor to transform it into a gaseous compound which is transported into the CVD reactor with a carrier gas such as hydrogen, helium, argon, or nitrogen. However, this procedure has proven to be problematic because of the inability to deliver, at a controlled rate, a reproducible flow of vaporizable precursor to the vaporizer.

Numerous semiconductor-manufacturing processes employ ion implantation for adding dopants (impurities), such as boron (B) and phosphorus (P) to a semiconductor substrate. Typically, an ion implanter includes an ion source that ionizes an atom or molecule of the material to be implanted. The generated ions are accelerated to form an ion beam that is directed toward a target, such as a silicon chip or wafer, and impacts a desired area or pattern on the target. The entire operation is carried out in a high vacuum.

The possibility of producing useful currents of a heavy gas phase molecular ion offers significant advantages over ion source material presently used in implanters. For example, using the heavy gas molecular ion, decaborane ion (B₁₀H₁₄⁺), which has ten boron atoms has advantages for low energy, high current dopant beam transport. However, decaborane is a low vapor pressure solid at room temperature, and as such, it is difficult to transport the material in a gaseous form at the flow rates required by the ion implant tool. In order to increase the flow rate of decaborane, typically, the material is heated and/or a vacuum is pulled.

Notably, difficulties still arise when attempting to control the flow rate. Typically, the flow rate is controlled by passing the decaborane through a mass flow controller (MFC). However, in order to avoid condensation, the MFC must be specially designed to allow for heating. This often increases the size of the MFC, which is not the optimal way to control the flow. Further, even if the decaborane makes it through the MFC, it can readily condense further downstream if a cold spot is encountered. This will have the effect of providing a lower flow rate than expected to the source chamber of the implanter. Conversely, if the temperature at the areas where the condensation occurs suddenly arises, the flow of decaborane will suddenly increase to the ion implanter. Thus, these issues make it difficult to achieve a steady flow rate, thereby causing poor yield or quality at the wafer.

Accordingly, there is need in the art for a source material delivery system that efficiently delivers all types of vaporizable precursors at a highly controllable and reproducible flow rate into a vaporizer.

### SUMMARY OF THE INVENTION

The present invention relates to a system for delivering a precursor source material at a controlled rate having particular utility for semiconductor manufacturing applications.

In one aspect, the present invention relates to a delivery system for a source material for vaporization, the system comprising:
a source material vessel comprising:
a) an interior chamber for placement of the source material;
b) a processing tool/vaporization chamber positioned downstream from the source material vessel; and
c) a droplet generator in fluid communication with the interior chamber of the source material vessel and processing tool/vaporization chamber and positioned therebetween, wherein the droplet generator device comprises:
   i) a plurality of nozzles in fluid communication with the interior chamber of the source material vessel and processing tool/vaporization chamber, wherein the nozzles comprise an aperture bore diameter sized to generate a droplet of source material for vaporization in the processing tool/vaporization chamber; and
   ii) a pressure producing means communicatively contacting the source material to cause an increased pressure within the source material thereby generating droplets of source material and causing the ejection of same through the nozzles into the processing tool/vaporization chamber.

In this embodiment, the pressure producing means may include a heating means to heat a portion of the source material to a flowable liquefied state to increase the pressure therein sufficiently to create expansion of the liquid through a nozzle. Preferably, the pressure is sufficient to create a bubble in the liquid material thereby causing expansion of the liquefied material through the nozzle. In the alternative, the pressure producing means may include a piezoelectric transducer that upon application of a voltage thereto, the transducer creates a vibration within the source material to displace liquefied source material through the nozzles thereby creating a droplet.

In another embodiment the present invention provides for a system for delivery of a source material for vaporization, the system comprising:
a) a source material vessel comprising:
   i) an interior chamber for placement of the source material:
   ii) a source heating means for heating at least a portion of the source material within the interior chamber to a flowable liquefied state;
b) a processing tool or source/vaporization chamber positioned downstream from the source material vessel; and
c) a droplet generator in fluid communication with the interior chamber of the source material vessel and processing tool or source/vaporization chamber and positioned therebetween, wherein the droplet generator device comprises:
   i) a plurality of nozzles in fluid communication with the interior chamber of the source material vessel and processing tool or source/vaporization chamber, wherein the nozzles comprise an aperture bore diameter sized to generate a predetermined droplet of the liquefied source material; and
   ii) a pressure producing means communicatively contacting the liquefied source material to cause an increased pressure within the liquefied source material thereby causing the ejection of droplets of the liquefied source material through the nozzles into the processing tool or source/vaporization chamber.

In yet another aspect, the present invention provides for a method of delivering a controlled flow of a source material to a downstream processing tool or source/vaporization chamber, the method comprising:
introducing the source material into a source material vessel;
liquefying the source material to a flowable state;
applying sufficient pressure by mechanical and/or thermal means, to the liquefied source material to increase pressure therewithin in a sufficient amount to eject the liquefied source material through a plurality of nozzles thereby generating droplets of the liquefied source material for introduction into the downstream processing tool or source/vaporization chamber.

Other aspects and features of the invention will be more fully apparent from the ensuing disclosure and appended claims.

### BRIEF DESCRIPTION OF THE DRAWINGS

FIG. 1 is a block diagram setting forth the basic components of one embodiment of the delivery system of present invention wherein the droplet generator is positioned vertically above the processing tool.

FIG. 2 illustrates another embodiment wherein the droplet generator is positioned horizontally adjacent to the processing tool.

FIGS. 3A-3C are cross-sectional views of another embodiment of a droplet generator and ejector device of the present invention illustrating use of a heating means to provide sufficient pressure to generate and eject a droplet of source material.

FIG. 4 is a side view of a droplet generator and ejector device of the present invention illustrating the use of a piezoelectric material to generate a pressure wave thereby ejecting a generated droplet from the an array of nozzles.

FIGS. 5A-5C illustrate aperture shapes applicable for the nozzles of the present invention.

FIGS. 6A and 6B illustrate nozzles structures of the present invention being circumvented with an annular space for introduction of a carrier gas concurrently with the droplet ejection.

FIG. 7 illustrates another embodiment of the present invention.

### DETAILED DESCRIPTION OF THE INVENTION AND PREFERRED EMBODIMENTS THEREOF

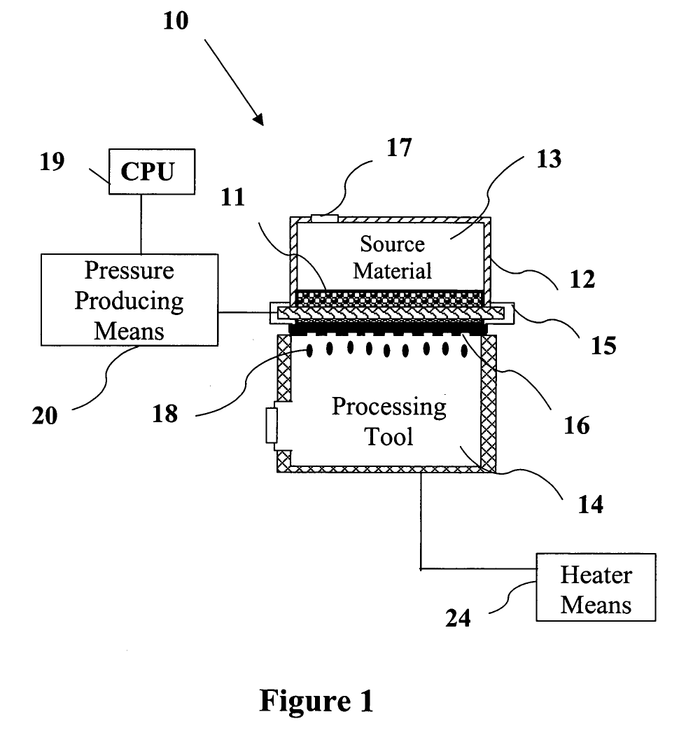

A delivery system in accordance with one embodiment of the present invention and illustrated in FIG. 1 overcomes the deficiencies of prior art delivery systems and introduces a controlled flow rate of source material into a processing tool. The delivery system 10 comprises a source material vessel 12, having an interior chamber 13 for holding a source material 11. Further, the source material vessel comprises an inlet port 17 for introducing a source material. The vessel is generally fabricated of a suitable material that will not react with enclosed source material. The fabrication material may include, but is not limited to silver, silver alloys, copper, copper alloys, aluminum, aluminum alloys, lead, nickel clad, stainless steel, graphite and/or ceramic material.

Positioned beneath the source material vessel 12 and in fluid communication therewith is a semiconductor processing tool 14. The processing tool may include any system that requires a vaporized source material for deposition or doping, such a CVD system, or an ion implantation system. Positioned between the source material vessel 12 and processing tool 14 is a droplet generator 15 of the present invention.

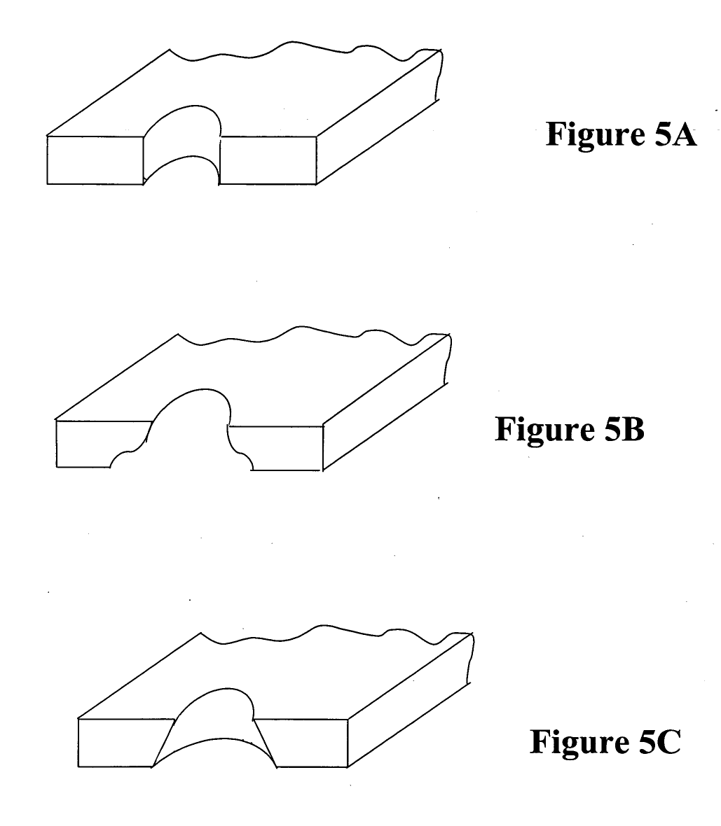

In the basic configuration, the droplet generator 15 comprises at least one nozzle 16, and more preferably, a plurality of nozzles in fluid communication with a liquefied or liquefiable source material retained in the source material vessel. The nozzle configuration is shaped to provide effective and unencumbered flow of the source material therethrough, and can include applicable configurations such as circular, elliptical, rectangular and the like. The nozzle geometry directly effects drop volume and ejection velocity, and as such, the aperture bore diameter and geometry should be considered when determining requirements of droplet sizes and frequency of formation. Various nozzle geometries are summarized in FIGS. 5A to 5C. FIG. 5A illustrates a cylindrical bore geometry, 5B illustrates a tapered bore geometry and 5C illustrates a convergent geometry, all of which provide droplet formation and unencumbered ejection at a relatively high frequency. Because small drop volume is required to achieve smaller drops thereby increasing the speed of vaporization of the generated droplets, the nozzle aperture bore diameter is preferably from about 1 urn to about 1000 μm, and more preferably from about 30 to 300 μm.

The quantity of nozzles incorporated into a droplet generator of the present invention is determined by the volume of each droplet, the velocity of the ejected drop, the refill flow rate into the nozzle area, the viscosity of the source material, and the required flow rate of source material into the processing tool. Preferably, the number of nozzles ranges from about 32 to about 400 per device, which, depending on the viscosity of the source material and droplet size, can generate from about 500 drops per second up to about 6000 drops per second. Thus, if a droplet is 100 um and approximately 1000 droplets are produced in a second then it can be calculated that a source material, such as decaborane, can be delivered to the processing tool at a flow rate of approximately 5 sccm.

The droplet generator of the present invention further comprises a pressure producing means to effectuate ejection of liquefied source material through the plurality of nozzles. In the FIG. 1, the pressure producing means 20 comprises a heating element that can rapidly heat the source material 11 in a sufficient amount to cause an increase in pressure within the contained source material. The heating element may include resistive heating systems, block heaters or induction heating devices. The heating element may be selectively activated through an electrode setup, which is in electrical contact with the heating element.

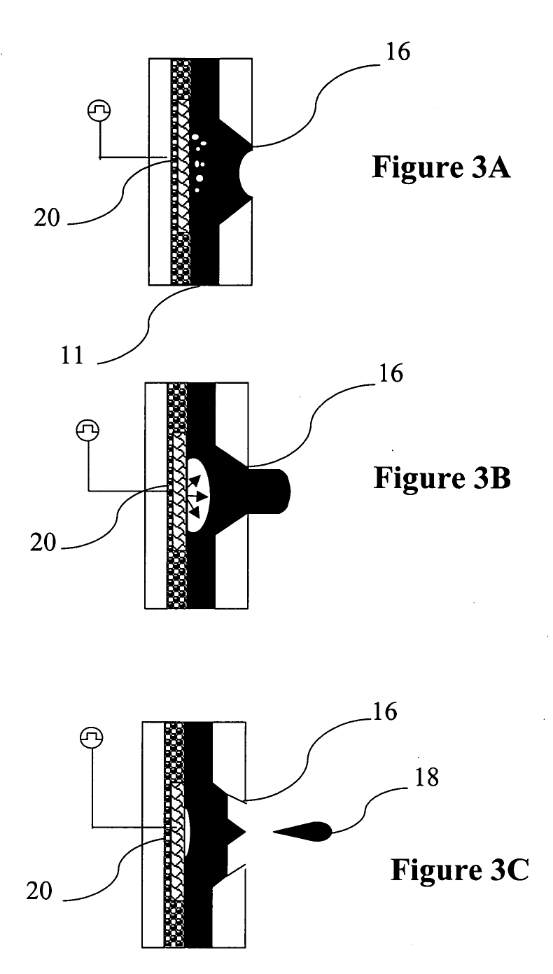

In use, a continuous current or a current pulse (periodic) of less than a few microseconds through the heater causes heat to be transferred from the surface of the heater to the source material. The source material, whether initially in a solid or liquid state, is preferably heated to the critical temperature for bubble nucleation as shown in FIG. 3A. When nucleation occurs, vapor bubbles instantaneously expand to force the source material 11 into the nozzle, as shown in FIG. 3B. The increased pressure within the source material and source material vessel container has to be greater than that within the processing tool and it should be noted that depending on the aperture bore size and configuration, the pressure requirements may increase to as much as 70 atms. As the bubble collapses, the increased pressure within the reservoir is reduced and a droplet 18 of source material breaks off and enters into the processing tool, as shown in FIG. 3C. This entire process can occur in the range from about 10 μs to about 50 μs depending on the heater temperature, viscosity of the source material and volume of the droplet. The liquefied source material can then refill the nozzle region and the entire process is ready to begin again. Depending on the physical properties of the source material, the refill time can range from about.50 μs to about 200 μs. Further, the volume of each droplet, which is again dependent on the aperture bore size and configuration, can be in the range from about 30 to about 1000 picoliters.

The delivery system of the FIG. 1 may further comprise a heating means 24 to effectuate the evaporation of the droplet of source material as it enters into the processing tool, if necessary. Any heating means that increases the temperature within the tool to a temperature sufficient to ensure vaporization of the generated droplets may be used in the present invention. Depending on the vaporizable source material, the operating conditions of the processing tool, the vapor pressure and flow rate of the droplets into the processing tool, the temperature suitable for vaporization may be in the range from about 30° C. to about 2000° C., and more preferably from about 100° C. to about 300° C.

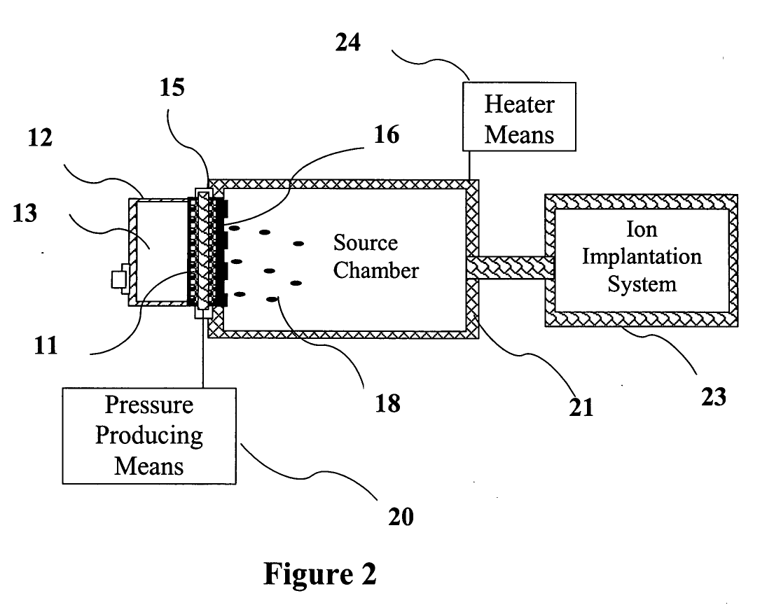

FIG. 2 illustrates another placement for the drop generator, wherein the drop generator is positioned laterally relative to the processing tool and the generated droplets are ejected horizontally into a source chamber 21 that is communicatively connected to an ion implantation system 23. The droplets can be directed horizontally into the source chamber of an ion implantation system, wherein the operating conditions can be tuned to provide the appropriate droplet size for vaporization. In this source chamber, the vapor phase molecules are ionized, usually with a positive charge (singly or multiply charged). The charged species are then accelerated (this is the ion beam) through an acceleration chamber where they are also separated by their mass and charge through the use of magnets. The ions left in the beam are then implanted into a wafer to a precise location.

Clearly, if the droplets are fired horizontally into the source chamber, they must evaporate before striking the bottom surface. Based on evaporation rate calculations, a 100 μm droplet will fall less than 5 millimeters before evaporating if the temperature is 100° C. and the pressure is 15 torr (see calculations in Example 1). Thus the horizontal nozzle placement must be positioned a sufficient distance above the bottom of the source chamber to ensure that there is sufficient time for evaporation of the droplet of source material so that ionization can occur. The source chamber 21 of FIG. 2, may further comprising a heating means 24 to ensure a sufficient temperature for evaporation of the generated droplets.

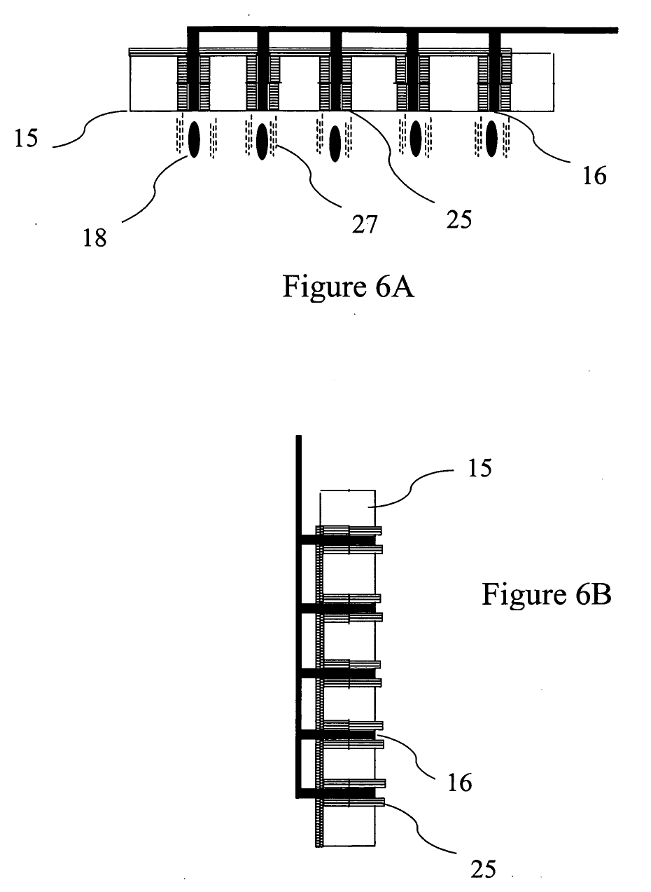

Depending on the source material, droplet size and viscosity, accommodations may be constructed into the droplet generator for introduction of a carrier gas to carry the generated droplets into the processing chamber. For example each nozzle may include an annular space 25 circumventing the nozzle 16 for flowing the carrier gas 27 concurrently with the generated droplets 18 as shown in FIG. 6A. Any carrier gas may be used, preferably a fluid that is essentially inert relating to reactivity with the source material. The nozzle 16 may extend the same distance longitudinally as the annular space section 25 or in the alternative, if premixing with the carrier gas is desirable, the nozzles 16 may be shortened or the annular space section 25 lengthened to provide an area for premixing of the source material and carrier gas before entry into the processing tool. Preferably, if the annular space extends beyond the nozzle opening, then the distance is sufficiently short to prevent deposition of the newly formed droplet within the annular space. The exact length of the annular space extension can be easily determined by the velocity of the ejecting droplet and the viscosity of the liquefied source material.

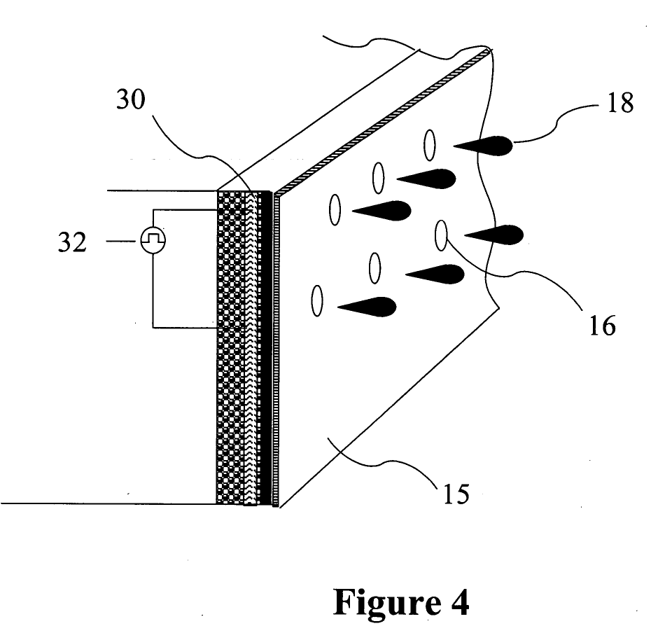

FIG. 4 illustrates another embodiment of the present invention wherein the droplet generator comprises an electromechanical transducer 30, as the pressure producing means, which generates a vibrational pressure wave to increase pressure within the liquefied source material. The most popular type of electromechanical transducers uses the piezoelectric effect. The piezoelectric effect occurs in several natural and artificial crystals and is defined as a change in the dimensions of the crystal when an electric charge is applied to the crystal faces. The importance of the piezoelectric effect is that the piezoelectric material provides a means of converting electrical oscillations into mechanical oscillations.

Any commonly used piezoelectric material may be utilized in the present invention including, but not limited to, modified lead titanate, quartz, barium titanate, lithium sulfate, lead-zirconate-titanate, and lead niobate. Examples of transducers which are commercially available and may be used in this present invention include: Matec broadband MIBO series (5-10 MHZ), Matec broadband MICO (3.5 MHZ), Matec broadband MIDO 2.25 MHZ), and Matec broadband MIEC series (50 kHz-1 MHZ).

The geometry of transducer 30 utilized in this invention can be any shape, such as circular or rectangular (linear arrays). It is important to note that in using a piezoelectric transducer the output from a separate variable-frequency oscillator or signal generator does not have to be applied to the transducer. The transducer can actually be part of the oscillator circuit itself, and it is the chosen resonance frequency of the piezoelectric crystal that stabilizes the frequency of the electrical oscillations. Applicable transducers will include types that produce vibrational acoustic wave within a range of frequencies (broadband) or for one specific frequency (narrowband) for frequencies ranging from hertz to gigahertz. Keeping this in mind any solid-state pulser or microprocessor 19, as shown in FIG. 1, can control pulse duration in the present invention.

If an oscillator or signal generator is used in combination with a piezoelectric transducer to produce a signal with predetermined characteristics such as frequency, pulse duration, and repetition rate, various oscillators or signal generators can be commercially purchased from a wide variety of manufacturers.

In use, the piezoelectric transducer 30 undergoes deformation when an electrical signal 32 generates a mechanical strain within the piezoelectric material. The piezoelectric material expands or bends and applies pressure to the source material. The deformation of the piezoelectric material causes an increased pressure within the source material thereby generating a pressure wave that propagates toward the nozzle to form a droplet of the source material ejected at the nozzle 16. Because the deformation of a piezoelectric transducer is on the submicron scale, the size of the piezoelectric transducer should preferably be of sufficient size to cause enough volume displacement to form a droplet. As such, the piezoelectric transducer preferably is at least as large as the bore diameter of the nozzle, and more preferably, at least twice the size of the bore diameter. Use of the piezoelectric transducer may be utilized with source material that is of such a nature that bubble nucleation does not occur at a reasonable heating temperature.

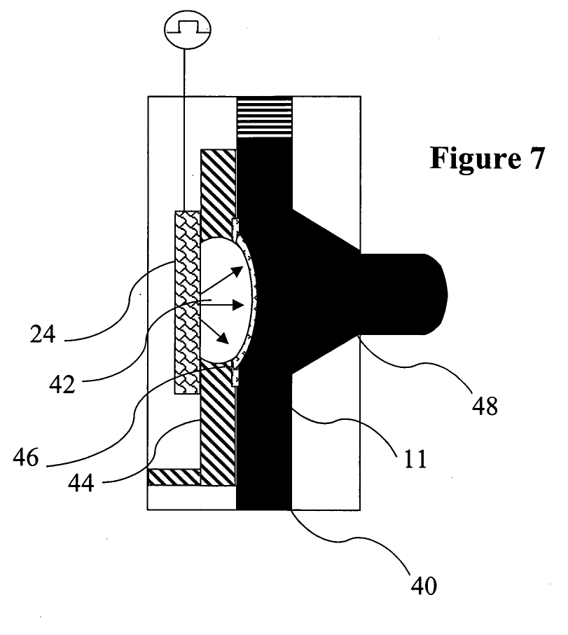

FIG. 7 illustrates yet another embodiment of the present invention that may be utilized with source material that is of such a nature that bubble nucleation does not occur at a reasonable heating temperature. This embodiment uses two separate and distinct reservoirs, separated by a common and expandable membrane. The source material 11 is contained in a primary reservoir 40 and a thermal fluid that forms nucleation bubbles 42 upon heating by heating means 24 is contained in a secondary reservoir 44. Positioned between the primary and secondary reservoir is a section of an expandable membrane 46 that reacts to increased pressure in the secondary reservoir and transfers such increased pressure into the primary reservoir. As the pressure increases in the primary reservoir, the source material 11 is forced into the nozzle 48 and if sufficient pressure is exerted, a droplet of source material is formed and ejected as discussed herein for other embodiments. The membrane is made of any suitable conventional resilient material, which is impervious to air and liquid and is resistant to breaking even at temperatures in the range of the boiling thermal fluids. Suitable materials include rubber, latex, neoprene, polypropylene, etc.

Any thermal liquid that easily nucleates into bubble formation may be used in the present invention. Among the applicable thermal fluids, water, isopropyl alcohol, hexane, propylene glycol have been found effective. Thermal fluids that boil at lower temperatures are especially desired because of the avoidance of increased heating and the cost benefit of increasing pressure without the requirement of high heating temperatures. Water is considered the most advantageous because it vaporizes easily, is plentiful and is the least expensive.

The present invention has the advantages of introducing a controlled and reproducible amount of source material into a vaporization vessel. The systems may include continuous or periodic flow depending on the device used for increasing the pressure within the source material enclosed in the reservoir. With this predictable and reproducible flow rate into the vaporization vessel, saturation of a carrier gas, if used, can be expected and the flow rate to the processing tool can be controlled thereby ensuring consistency in the end product. The system may further comprise sensing means to determine flow rate communicatively connected to a monitoring system and control signal to produce a required flow rate of liquid droplets. That is, for example for a given voltage input, the system would eject droplets at a given frequency in order to achieve a given overall vapor flow rate.

The present invention may be used with any type of source material that can be liquefied either by heating or solubilization in a solvent including but not limited to decaborane, (B₁₀H₁₄), pentaborane (B₅H₉), octadecaborane (B₁₈H₂₂), boric acid (H₃BO₃), SbCl₃, and SbCl₅. Others that potentially might be used are AsCl₃, AsBr₃, AsF₃, AsF₅, AsH₃, As4O₆, As₂Se₃m As₂S₂, As₂S₃, As₂S₅, As₂Te₃, B₄H₁₁, B₄H₁₀, B₃H₆N₃, BBr₃, BCl₃, BF₃, BF₃.O(C₂H₅)₂, BF₃.HOCH₃, B₂H₆, F₂, HF, GeBr₄, GeCl₄, GeF₄, GeH₄, H₂, HCl, H₂Se, H₂Te, H₂S, WF₆, SiH₄, SiH₂Cl₂, SiHCl₃, SiCl₄, SiH₃Cl, NH₃, NH₃, Ar, Br₂, HBr, BrF₅, CO₂, CO, COCl₂, COF₂, Cl₂, ClF₃, CF₄, C₂F₆, C₃F₈, C₄F₈, C₅F₈, CHF₃, CH₂F₂, CH₃F, CH₄, SiH₆, He, HCN, Kr, Ne, Ni(CO)₄, HNO₃, NO, N₂, NO₂, NF₃, N₂O, C₈H₂₄O₄Si₄, PH₃, POCl₃, PCl₅, PF₃, PF₅, SbH₃, SO₂, SF₆, SF₄, Si(OC₂H₅)₄, C₄H₁₆Si₄O₄, Si(CH₃)₄, SiH(CH₃)₃, TiCl₄, Xe SiF₄, WOF₄, TaBr₅, TaCl₅, TaF₅, Sb(C₂H₅)₃, Sb(CH₃)₃, In(CH₃)₃, Pbr₅, PBr₃, and RuF₅.

Also, solvents (organic or inorganic) containing forms of arsenic, phosphorus, antimony, germanium, indium, tin, selenium, tellurium, fluorine, carbon, boron, aluminum, bromine, carbon, chlorine, nitrogen, silicon, tungsten, tantalum, ruthenium, selenium, nickel, and sulfur may be used in the present invention.

### EXAMPLE 1

A system such as described in FIG. 1 is used to produce vaporized decaborane for use in an ion implantation system. In operation, the delivery system of the present invention introduces solid decaborane into the source material vessel, which is placed directly over a source chamber in an ion implantation system. Because the temperature required to melt decaborane (100° C.) will accelerate its decomposition, only the bottom surface of the solid decaborane will be heated. Thus, the heating means will be positioned beneath the solid source material. The heat will cause the bottom surface of the solid source material to melt and drip into the nozzle area. Heating preferably is accomplished by a vertical support piece comprising a resistive heating device. Further, to ensure consistent temperature during the droplet generation and ejection, the nozzle plate comprising a plurality of nozzles may be heated.

The quantity of nozzles is preferably between 600 to 1000 wherein each nozzle has a nozzle bore diameter sized to generate a droplet size of 60 to 100 microns. For a droplet size of 100 microns, approximately 1000 droplets/sec are required in order to produce a gaseous decaborane flow rate of 5 sccm. The droplet formation rate can be precisely controlled via simple electrical signals to the heating device. The precision can be as small as 8.33×10⁻⁵ sccm if the control is on a 1 droplet per second basis.

The parameters of the system regarding the preferred droplet, evaporation rate, heating temperature, can be easily determined using the following equations with known values for the physical parameters of decaborane and droplet evaporation discussion as set forth in Turns, S. R., An Introduction to Combustion—Concepts and Applications, McGraw Hill, Boston, Mass., 2000, the entire contents of which is hereby incorporated by reference herein for all purposes.

The following program determines the time required to evaporate a droplet of decaborane.

| | |
|---|---|
| T_{bp} = 180 | {Boiling point for Decaborane, C} |
| T_{N2} = 100 | {Nitrogen ballast temperature, C} |
| D = 100 | {Droplet diameter, um} |
| P = 15 | {Pressure, torr} |
| T_{liq} = 100 | {Temperature of Decaborane droplet, C} |
| R = 8.314 | {Gas Constant; J/mol/K} |
| T_{k,liq} = T_{liq} + 273.15 | {Temperature of decaborane droplet, K} |
| T_{k,N2} = T_{N2} + 273.15 | {Nitrogen ballast temperature, K} |

Density of Decaborane liquid as a function of temperature; from reference
[1]. p. 207

| | |
|---|---|
| A = 0.31796 | {Constant} |
| B = 0.3 | {Constant} |
| | {Constant} |
| n = 0.28571 | |
| ρₗ = A · B^{-(1-T}^{_{k,liq}}^{/T}^{_{c}}⁾^{ⁿ} | {Density, kg/liter} |
| Molecular Weights | |

| | |
|---|---|
| MW_{N2} = 2 · 14.007 | {Nitrogen; grams/mole} |
| MW_{B10H14} = 10 · 10.811 + 14 · 1.008 | {Decaborane; grams/mole} |
| MW_{AB} = 2 · ((1/MW_{N2} + 1/MW_{B10H14})⁻¹) | {Mixture; grams/mole} |

Critical constants for Decaborane

| | |
|---|---|
| Tc = 791.78 | {Critical temperature; K.} |
| Pc = 59.02 | {Critical pressure; Bar} |
| Vc = 334.6 | {Critical volume; cm³/mol} |

Determination of collision diameters and collision integral

| | |
|---|---|
| k_{B} = 1.3804 × 10⁻²³ | {Boltzman constant; Joule/molecule-K} |
| σ_{B10H14} = 9.6 | {B₁₀H₁₄ collision diameter; Å, ref. [3]} |
| ∈_{B10H14}/k_{B} = 0.77 · T_{c} | Energy of attaction between B₁₀H₁₄ |
| | molecules; |
| | epsilon [=] Joule/molecule; ref [2]; p. 22} |
| σ_{N2} = 3.798 | {N₂ collision diameter, angstroms; ref. [4]; |
| | p. 658} |
| ∈_{N2}/k_{B} = 71.4 | {Energy of attraction between N₂ molecules; |
| | epsilon [=] Joule/molecule; ref [4]; p. 658} |
| | {Mixture collision diameter, Å ref [4]; |
| | p. 658} |
| σ_{AB} = 0.5 · (σ_{N2} + σ_{B10H14}) | |
| | {Energy of attaction for the mixture} |
| ∈_{AB} = (∈_{B10H14} · ∈_{N2})^{1/2} | |
| | {Dimensionless temperature; ref [4]; p. 657} |
| Tₛₜₐᵣ = k_{B} · T_{N2}/∈_{AB} | |
| aa = 1.06036 | {Constant} |
| bb = 0.15610 | {Constant} |
| cc = 0.19300 | {Constant} |
| dd = 0.47635 | {Constant} |
| ee = 1.03587 | {Constant} |
| ff = 1.52996 | {Constant} |
| gg = 1.76474 | {Constant} |
| hh = 3.89411 | {Constant} |

${Ω}_{D} = ( \frac{aa}{{T}_{star}^{bb}} ) + ( cc / exp ( dd \cdot {T}_{star} ) ) + ( ee / exp ( ff \cdot {T}_{star} ) ) + ( gg / exp ( hh \cdot {T}_{star} ) )$

Collision integral

Diffusivity of Decaborane in N₂; see ref [4]; p. 658

| | |
|---|---|
| ${D}_{AB} = \frac{0.0266 \cdot {T}_{k , N2}^{3 / 2}}{( ( P \cdot 101325 / 760 ) \cdot ( {MW}_{AB}^{0.5} ) \cdot {σ}_{AB}^{2} \cdot {Ω}_{D} )}$ | {Diffusivity; m²/sec} |

Vapor Pressure; range 333.15 K-436.95 K

| | |
|---|---|
| a3 = 4813.9118 | {Constant} |
| b3 = −1.2837 × 10⁵ | {Constant} |
| c3 = −1.9845 × 10³ | {Constant} |
| d3 = 1.9935 | {Constant} |
| e3 = −7.8068 × 10⁻⁴ | {Constant} |

| | |
|---|---|
| ${P}_{vap} = {10}^{a3 + b3 / {T}_{k , liq} + c3 \cdot log ( {T}_{k , liq} ) + d3 \cdot {T}_{k , liq} + e3 \cdot {T}_{k , liq}^{2}}$ | {Vapor Pressure, Torr, ref 1[1]; p. 180} |

| | |
|---|---|
| x_{B10H14,s} = P_{vap/P} | {mole fraction B₁₀H₁₄ at interface} |

Mixture Molecular Weight: grams/mole

MWₘᵢₓ = x_{B10H14,s} · MW_{B10H14} + (1 − x_{B10H14,s}) · MW_{N2}

Droplet/vapor interface: B₁₀H₁₄ mass fraction

Y_{B10H14,s} = x_{B10H14,s} · MW_{B10H14}/MWₘᵢₓ

Mean gas density

| | |
|---|---|
| ρ_{N2} = ρ(N2, T = T_{N2}, | {N₂ density} |
| P = P · 101.325/760) | |
| MWₘₑₐₙ = 0.5 · (MWₘᵢₓ + MW_{N2}) | {Mean molecular weight} |
| ${ρ}_{mean} = \frac{P \cdot 101325 / 760}{( ( 8314 / {MW}_{mean} ) \cdot {T}_{k , N2} )}$ | {mean density; density; kg/m³} |

Determine B_{Y}; see ref [4]; chapter 3
Y_{B10H14,inf} = 0
$1 + {B}_{Y} = \frac{1 - {Y}_{B10H14 , inf}}{1 - {Y}_{B10H14 , s}}$
Determine K; see ref [4]; chapter 3
$K = ( 8 \cdot {ρ}_{mean} \cdot \frac{{D}_{AB}}{ρl \cdot 1000} ) \cdot ln ( 1 + {B}_{Y} )$

| | |
|---|---|
| Droplet lifetime | |
| ${t}_{d} = \frac{{( D \cdot 1 \times {10}^{- 6} )}^{2}}{K}$ | {seconds} |

Maximum distance dropped vertically

| | |
|---|---|
| g = 9.8 | {acceleration due to gravity; m/sec²} |
| Dᵥₑᵣₜ = 0.5 · g · t_{d}² | {meters dropped vertically prior to |
| | complete evaporation} |

While the invention has been described herein with reference to specific embodiments and features, it will be appreciated the utility of the invention is not thus limited, but encompasses other variations, modifications, and alternative embodiments. The invention is, accordingly, to be broadly construed as comprehending all such alternative variations, modifications, and other embodiments within its spirit and scope, consistent with the following claims.

### REFERENCES

All references are hereby incorporated by reference herein in their entirety for all purposes.
[1] Yaws, C. L., Chemical Properties Handbook, 7th ed., McGraw-Hill, New York, 1999
[2] Bird, R. B., W. E. Stewart, and E. N. Lightfoot, Transport Phenomena, p. 510, John Wiley and Sons, New York, 1960
[3] Miller, G., “The Vapor Pressure of Solid Decaborane,” Journal of Physical Chemistry, Vol 67, p. 1363-1364, 1963.
[4] Turns, S. R., An Introduction to Combustion—Concepts and Applications, McGraw Hill, Boston, Mass., 2000.

What is claimed is:

1. A delivery system for a source material for vaporization, the system comprising:
a) a source material vessel comprising:
i) an interior chamber for placement of the source material:
b) a vaporization chamber positioned downstream from the source material vessel; and
c) a droplet generator in fluid communication with the interior chamber of the source material vessel and vaporization chamber and positioned therebetween, wherein the droplet generator device comprises:
i) a plurality of nozzles in fluid communication with the interior chamber of the source material vessel and vaporization chamber, wherein the nozzles comprise an aperture bore diameter sized to generate a droplet of source material for vaporization in the vaporization chamber; and
ii) a pressure producing means communicatively contacting the source material to cause an increased pressure within the source material thereby generating droplets of source material and causing the ejection of same through the nozzles into the vaporization chamber.

2. The system according to claim 1, wherein the pressure producing means comprises a heating means.

3. The system according to claim 1, wherein the pressure producing means comprises an electromechanical transducer.

4. The system according to claim 3, wherein an electrical charge is applied to the electromechanical transducer to cause mechanical strain therein and transferring such mechanical strain to liquefied source material.

5. The system according to claim 3, wherein the electromechanical transducer comprises a piezoelectric material.

6. The system according to claim 5, wherein the piezoelectric material is deformed thereby causing increased pressure to generate a pressure wave that propagates towards the nozzle to form a droplet of the liquefied source material and ejection therefrom.

7. The system according to claim 6, wherein the piezoelectric material is selected from the group consisting of lead titanate, quartz, barium titanate, lithium sulfate, lead-zirconate-titanate and lead niobate.

8. The system according to claim 1, wherein the vaporization chamber further comprises a heating means.

9. The system according to claim 1, wherein the plurality of nozzles have an aperture bore diameter of about 30 μm to about 300 μm.

10. The system according to claim 9, the droplet generator comprises from about 32 to about 400 nozzles per device.

11. The system according to claim 2, wherein the second heating means comprises a resistive heating system, a block heater or an induction-heating device.

12. The system according to claim 2, wherein the vaporization chamber is communicatively connected to an ion implantation system.

13. A method of delivering a controlled flow of a source material to a downstream processing tool, the method comprising:
a) introducing the source material into a source material vessel;
b) liquefying the source material to a flowable state;
c) applying sufficient pressure to the liquefied source material to increase pressure therewithin in an amount to eject the liquefied source material through a plurality of nozzles thereby generating droplets of the liquefied source material for introduction into the downstream processing tool or source chamber for an ion implantation system.

14. The method according to claim 13, wherein the nozzles comprise an aperture bore diameter sized to generate a droplet of source material for evaporation in the downstream processing tool or source chamber.

15. The method according to claim 13, wherein pressure is applied on the source material by supplying heat in an amount sufficient to cause bubble nucleation in the source material.

16. The method according to claim 13, wherein pressure is applied on the source material by contacting liquefied source material with an electromechanical material that when electrically stimulated causes mechanical strain within the electromaterial in an amount sufficient to cause a pressure wave that generates a droplet of source material and ejects same from the nozzles.

17. A system for delivery of a source material for vaporization, the system comprising:
a) a source material vessel comprising:
i) an interior chamber for placement of the source material:
ii) a source heating means for heating at least a portion of the source material within the interior chamber to a flowable liquefied state;
b) a processing tool or source/vaporization chamber positioned downstream from the source material vessel; and
c) a droplet generator in fluid communication with the interior chamber of the source material vessel and processing tool or source/vaporization chamber and positioned therebetween, wherein the droplet generator device comprises:
i) a plurality of nozzles in fluid communication with the interior chamber of the source material vessel and processing tool or source/vaporization chamber, wherein the nozzles comprise an aperture bore diameter sized to generate a predetermined droplet of the liquefied source material; and
ii) a pressure producing means communicatively contacting the liquefied source material to cause an increased pressure within the liquefied source material thereby causing the ejection of droplets of the liquefied source material through the nozzles into the processing tool or source/vaporization chamber.

18. The system according to claim 17, wherein the source material is a solid.

19. The system according to claim 17, wherein the liquefied source material has low boiling temperature.

20. The system according to claim 17, wherein the plurality of nozzles have an aperture bore diameter of about 30 μm to about 300 μm.

21. The system according to claim 17, the droplet generator comprises from about 32 to about 400 nozzles.

22. The system according to claim 17, wherein the heating means comprises a resistive heating system, a block heater or an induction-heating device.

23. The system according to claim 17, wherein the nozzles further comprises an annular space circumventing the nozzle for flowing a carrier gas concurrently with the ejection of the liquefied source material through the nozzles into the processing tool or source/vaporization chamber.

24. The system according to claim 23, wherein the annular space extends beyond the nozzle, thereby providing an area of premixing before entry into the processing tool or source/vaporization chamber.
